(19) United States
(12) Patent Application Publication
(10) Pub. No.: US 2026/0096385 A1
(43) Pub. Date: Apr. 2, 2026

(54) ADHESIVE TAPE APPLICATION SYSTEM TO MODIFY THE ADHESIVE STRENGTH OF THE ADHESIVE TAPE AND METHOD OF APPLYING THE ADHESIVE TAPE

(71) Applicant: Taiwan Semiconductor Manufacturing Company Limited, Hsinchu (TW)

(72) Inventors: An-Dih Yu, New Taipei City (TW); Wen-Yi Lin, New Taipei City (TW); Yu-Sheng Wang, Hsinchu City (TW); Cheng-Xuan Wu, Hsinchu (TW); Zhihua Zou, Hsinchu (TW)

(21) Appl. No.: 19/004,372

(22) Filed: Dec. 29, 2024

Related U.S. Application Data
(60) Provisional application No. 63/701,608, filed on Oct. 1, 2024.

(51) Int. Cl. H01L 21/67; C09J 5/00

(52) U.S. Cl. CPC H10P 72/0442; C09J 5/00; C09J 2203/326; C09J 2301/416

(57) ABSTRACT

An adhesive tape application system includes an adhesive tape dispenser configured to dispense adhesive tape, a laminating unit configured to laminate the adhesive tape on a workpiece, and a photo-treatment device between the adhesive tape dispenser and the laminating unit and configured to perform photo-treatment of the adhesive tape to tune an adhesive strength of the adhesive tape.

### RELATED APPLICATIONS

This application claims the benefit of priority to U.S. Provisional Application No. 63/701,608, entitled “In-Situ tape photo-treatment for adhesive strength tuning,” filed on Oct. 1, 2024, the entire contents of which are incorporated by reference herein for all purposes.

### BACKGROUND

Semiconductor Device fabrication may sometimes require the precise application of adhesive tape to a workpiece. In semiconductor device fabrication, adhesive tape may be applied to a surface of a semiconductor wafer. One type of adhesive tape that may be applied to a semiconductor wafer is dicing tape. Dicing tape is a specialized adhesive tape that may be used to hold the semiconductor wafer securely in place during a dicing process. The dicing process may involve dicing (e.g., cutting, or singulating) the wafer into individual dies or chips, which may constitute final, separate semiconductor components.

Dicing tape may have an adhesive strength that retains the semiconductor wafer and individual die in place during cutting but may be easily removed afterward without leaving residue or damaging the die. The dicing tape may include a “UV tape” that is designed to lose tackiness (i.e., adhesion) upon exposure to UV light, making the removal process easier and reducing the chance of die damage.

The dicing process may subject the semiconductor wafer to mechanical stresses. The dicing tape may provide a stable base to prevent shifting or vibration that could lead to die cracking or misalignment. The dicing tape may protect a front side of the wafer from chipping or scratching during dicing. The dicing tape may also help ensure clean, precise cuts by keeping each die securely in place until they are ready for the next fabrication and/or packaging step.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic illustration of an adhesive tape application system according to one or more embodiments.

FIG. 1B is a schematic illustration of the photo-treatment device according to one or more embodiments.

FIG. 1C is another schematic illustration of the photo-treatment device according to one or more embodiments.

FIG. 2A is a top-down view of a semiconductor wafer that may be a workpiece in the adhesive tape application system according to one or more embodiments.

FIG. 2B is a vertical cross-sectional view of a region of the semiconductor wafer along the vertical plane B-B′ of FIG. 2A, according to one or more embodiments.

FIG. 2C is an exploded view of the semiconductor wafer including the irradiated portion of adhesive tape according to one or more embodiments.

FIG. 3 is a flowchart illustrating a method of applying adhesive tape to a workpiece according to one or more embodiments.

FIG. 4A is a schematic illustration of a photo-treatment device having a first alternative configuration according to one or more embodiments.

FIG. 4B is a schematic illustration of a photo-treatment device having a second alternative configuration according to one or more embodiments.

FIG. 5 is a schematic illustration of the adhesive tape application system having a first alternative configuration.

FIG. 6 is a schematic illustration of an adhesive tape application system 600 according to one or more embodiments.

FIG. 7 is a schematic block diagram of the control unit according to one or more embodiments.

FIG. 8 is a schematic illustration of the adhesive tape application system 50 having a second alternative configuration.

### DETAILED DESCRIPTION

The following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition to dicing tape, other types of adhesive tape may be applied to a semiconductor wafer during semiconductor device fabrication. For example, back grinding tape may be applied to a semiconductor wafer to protect a frontside of the semiconductor wafer (e.g., the active side which may include active devices such as transistors, diodes, operational amplifiers, etc.) during a back grinding process. The back grinding process may be used to thin the semiconductor wafer to the desired thickness. The back grinding tape may provide temporary bonding and can withstand mechanical stresses during the grinding process.

Other types of adhesive tape used in semiconductor fabrication may include, wafer mounting tape may be applied to the semiconductor wafer to temporarily secure the semiconductor wafer during handling or processing steps such as back grinding, wafer probing, or testing. Wafer mounting tape may have strong adhesive properties and is designed for easy release to avoid wafer damage during detachment.

Further, protection tape may be applied to the semiconductor wafer to protect specific areas of the semiconductor wafer, such as the front side or delicate circuitry, from mechanical damage, contamination, or chemical exposure during various fabrication processes. The protection tape may be designed to be durable, chemically resistant, and easily removable without leaving residue. They may be used during processes like etching, plasma treatments, or wafer handling.

Moreover, electrostatic discharge (ESD) tape may be applied to the semiconductor wafer to protect the semiconductor wafer from electrostatic discharge during handling and transport. The ESD tape may be made with conductive or anti-static materials that help dissipate static electricity, preventing damage to sensitive semiconductor components.

As with dicing tape, the other adhesive tapes may include a “UV tape” which has an adhesive strength that is diminished following the exposure to UV light. This may allow the adhesive tape to be easily removed from the semiconductor wafer by exposing the adhesive tape to UV light.

Each of the adhesive tapes may include a backing and a layer of the adhesive on the backing. The backing may be formed of a transparent material such as polyethylene terephthalate (PET). The adhesive may include, for example, an acrylic-based adhesive or a polyolefin-based adhesive which may provide strong adhesion during wafer processing and lose their tackiness after UV light exposure. Other adhesives (e.g., silicone-based adhesives, epoxy-based adhesives, polyurethane-based adhesives, etc.) may also be engineered to undergo a reduction in adhesion strength upon UV light exposure.

The process of applying the adhesive tape to a semiconductor wafer in semiconductor fabrication may begin by cleaning a semiconductor wafer to remove any particles, contaminants, or debris that could interfere with the adhesion of the adhesive tape. The cleaning process may be done, for example, using chemical solvents, ultra-pure water, and drying processes. The adhesive tape may then be applied to the cleaned surface of the semiconductor wafer.

Depending on the purpose of the adhesive tape, the adhesive tape may be applied to a frontside (e.g., active side) or backside (e.g., non-active side) of the semiconductor wafer, ensuring that there are no air bubbles or wrinkles located under the adhesive tape that could affect processing. A lamination process may then be performed to laminate the adhesive tape on the semiconductor wafer. In the lamination process, pressure may be applied to the adhesive tape, often using rollers, to ensure the adhesive tape adheres uniformly across the surface of the semiconductor wafer. The applied pressure may help to ensure that the tape securely sticks to the semiconductor wafer and prevents any misalignment or uneven attachment. After the lamination process is performed, excess adhesive tape around the edges of the semiconductor wafer may be trimmed using a precision cutting tool or edge trimming machine. Alternatively, the adhesive tape may be precut (e.g., perforated) to have a size and shape that substantially matches the size and shape of the workpiece, in which case no cutting may be necessary after the lamination process is performed.

In an adhesive tape application process, it may be desirable to use adhesive tapes with different adhesive strengths depending, for example, upon the workpiece on which the adhesive strength is to be applied. A first adhesive strength may be desired where the workpiece includes a first material and a second adhesive strength less than the first adhesive strength may be desired where the workpiece includes a second material different than the first material.

Currently, to provide a desired adhesive strength, batches of adhesive tapes may be segregated according to the adhesive strength indicated in the batch certificate of analysis (CoA). The adhesive tape may be selected for use from a batch having a desired adhesive strength (higher or lower batch) based on the batch CoA. The adhesive strength may also diminish over time, so batches with a higher adhesive strength may be allowed to set idle in a warehouse and wait for the adhesive strength to naturally diminish.

Thus, the adhesive strength of tape may rely completely on the in-coming CoA. The operator may use tape pre-use/pre-qual and change a tape batch to select an adhesive tape that best matches a desired adhesive strength. The process of tape pre-use/pre-qual and changing the tape batch may result in a large amount of wasted production time. Further, in instances in which a serious tape residue issue or pick-up fail issue occurs, there may be few options for resolving those kinds of problems in the fabrication section.

At least one embodiment of the present disclosure may include in-situ tape photo-treatment for adhesive strength tuning. Treating the adhesive tape in-situ may help to achieve precise tape adhesive-strength tuning for advanced technology. Thus, an operator may not be required to use tape pre-use/pre-qual and change a tape batch to select an adhesive tape, which may help to avoid wasted production time.

In particular, at least one embodiment may include an adhesive tape application system (e.g., wafer dicing tape lamination tool) that may allow for dynamic control of an adhesive strength of the adhesive tape. The adhesive tape application system may include, for example, one or more pro-active adhesive strength tuning knobs (control knobs) allowing the operator to control the tape adhesive strength control based on a type (e.g., material, die type, die size, etc.) of the workpiece (e.g., SoC, SoIC, HBM, etc.). In contrast, the current related processes have no such pro-active tuning knob (control knob) and the tape adhesive strength is static (i.e., unchangeable) during the tape application process.

In addition, a desirable adhesive strength may depend at least in part on a size of the dies in the workpiece (e.g., semiconductor wafer such as a silicon wafer). Thus, adhesive strength tuning may become increasingly desirable since there may be different adhesive strength criteria for different die sizes. By using the adhesive tape application system of the one or more embodiments, one universal tape may serve several different die applications, reducing production time and saving time and money.

In at least one embodiment, the adhesive strength may be tuned (e.g., reduced) by photo-treatment before application of the adhesive tape (e.g., BG tape, dicing tape, protection tape etc.). In the adhesive tape application system, the adhesive tape may include a photo-sensitive tape (e.g., UV tape). The adhesive tape application may include a light source and a lamination roller. The workpiece may include a semiconductor wafer. Light from the light source may be used to perform photo-treatment (i.e., illuminate) of the adhesive tape and in-situ adhesive strength tuning for proper taping.

In at least one embodiment, the light source may perform photo-treatment right before tape lamination (e.g., on a semiconductor wafer). The light from the light source may have a wavelength in a range from 200 nm to 700 nm. A distance between the photo-treatment and tape lamination on the workpiece may be less than 2 meters. A distance between light source and the adhesive tape may be in a range from 0.1 cm to 30 cm. An exposure time of exposing the adhesive tape to radiation by the light may be in a range from 0.1 second to 1000 seconds. The adhesive tape may include an acrylic-based UV tape. A potential lamination wafer surface may include, for example, at least one of Si, SiC, solder and PI, glycol ether-type protection layer, molding layer, an underfill layer, and a metal layer.

The light source may have a plurality of different geometries. In particular, the light source of photo-treatment may be a bar-type light source or plate-type light source. The photo treatment may occur right before tape lamination on the workpiece (e.g., semiconductor wafer).

The one or more embodiments may include several different novel aspects. In particular, a suitable light wavelength, light intensity, controllable exposure time, etc. may be utilized for different tapes, different die sizes, etc. The photo-treatment may be performed just before lamination for precise tape adhesive-strength tuning. The one or more embodiments may avoid pick-up fail, tape residue and other adhesive strength-related tape issues.

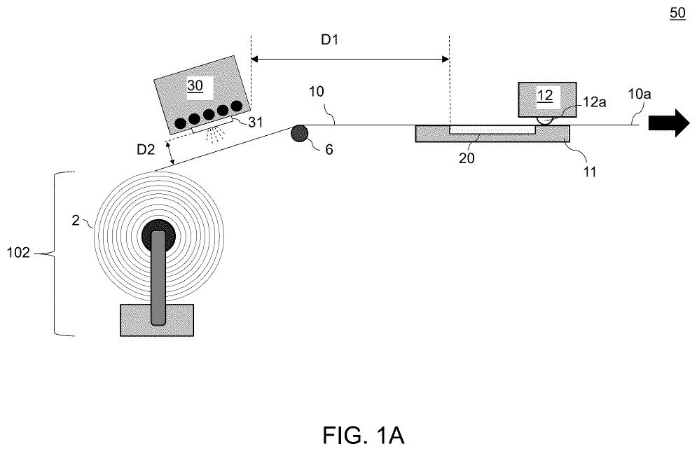

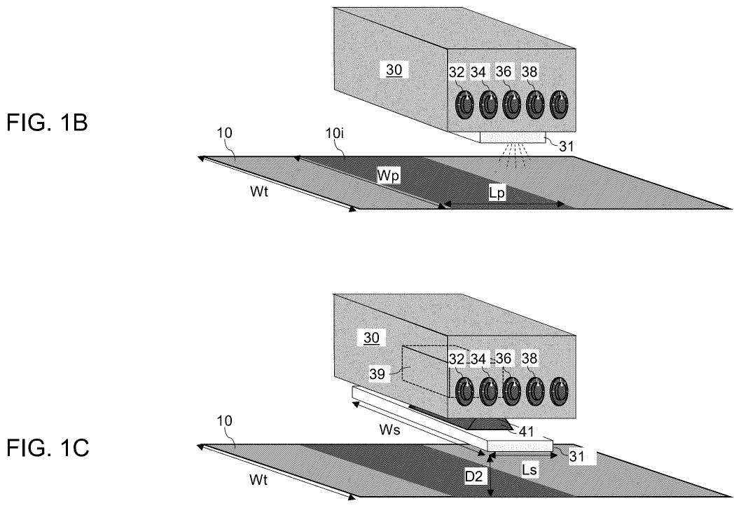

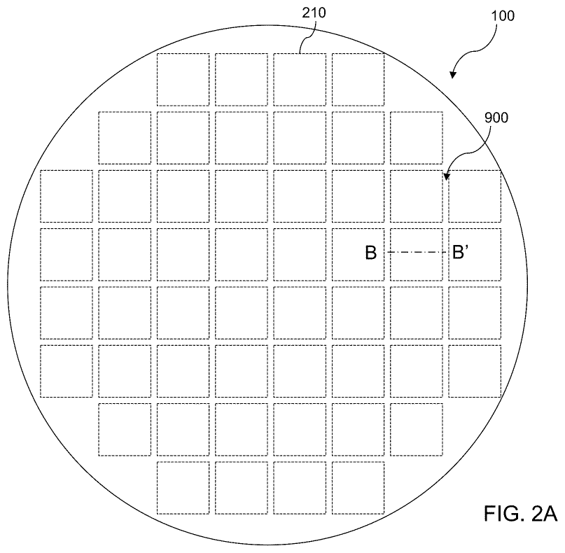

FIG. 1A is a schematic illustration of an adhesive tape application system 50 according to one or more embodiments. The adhesive tape application system 50 may apply adhesive tape 10 (e.g., photo-sensitive tape, UV tape, etc.) to a workpiece 20 such as a semiconductor wafer. As illustrated in FIG. 1A, the adhesive tape application system 50 may include an adhesive tape dispenser 102 configured to dispense adhesive tape 10, a laminating unit 12 configured to laminate the adhesive tape 10 on a workpiece 20, and a photo-treatment device 30 between the adhesive tape dispenser 102 and the laminating unit 12. The photo-treatment device 30 may be configured to perform photo-treatment of the adhesive tape 10 to tune (i.e., dynamically modify) an adhesive strength of the adhesive tape 10.

The adhesive tape dispenser 102 may include a tape supply roll 2 including the adhesive tape 10 wound around a cylinder such as a cardboard tube. The adhesive tape 10 may include, for example, back grinding tape, dicing tape, ESD tape, or protection tape. Other types of adhesive tape are within the contemplated scope of disclosure. The adhesive tape 10 may include a backing composed of a transparent material such as polyethylene terephthalate (PET). The adhesive tape 10 may also include a layer of adhesive on the backing. The adhesive may include, for example, an acrylic-based adhesive or a polyolefin-based adhesive. Other materials for the backing and the adhesive in the adhesive tape 10 are within the contemplated scope of disclosure.

The adhesive tape 10 may be dispensed manually from the adhesive tape dispenser 102 by pulling on a distal portion 10a of the adhesive tape 10 in a tape advancing direction indicated by the directional arrow in FIG. 1A. In particular, pulling on the distal portion 10a of the adhesive tape 10 may cause the cylinder with the tape supply roll 2 to rotate and dispense the adhesive tape 10. The distal portion 10a of the adhesive tape 10 may be pulled manually by an operator or electronically by an electromechanical pulling device.

The adhesive tape application system 50 may also include one or more tension bars 6 between the adhesive tape dispenser 102 and the laminating unit 12. The tension bar 6 may apply an upward force on the adhesive tape 10 that has been dispensed from the adhesive tape dispenser 102. The tension bar 6 may also maintain tension on the adhesive tape 10 as the adhesive tape 10 that has been dispensed from the adhesive tape dispenser 102. The tension bar 6 may include, for example, a cylindrical rod that extends substantially perpendicular to the adhesive tape advancing direction. The tension bar 6 may traverse the width of the adhesive tape 10 and be fixed to a wall, bracket, etc. In at least one embodiment, the tension bar 6 may include a roller that is engineered to rotate with a pulling of the adhesive tape 10.

The adhesive tape application system 50 may also include a workpiece stage 11. The workpiece stage 11 may securely hold the workpiece 20 in place during the tape application process, usually through vacuum suction or mechanical clamps. The workpiece 20 may be seated in a recess of the workpiece stage 11 so that an upper surface of the workpiece 20 is substantially coplanar with a upper surface of the workpiece stage 11.

In at least one embodiment, the workpiece 20 may include a semiconductor wafer such as a silicon wafer. In particular, the workpiece 20 may include a lamination surface (e.g., upper surface) including at least one of silicon, silicon carbide (SiC), solder (e.g., a layer of SnAgCu solder, SnCu solder, etc.), an organic polymer layer, a polyimide (PI) layer, a glycol ether-type protection layer, a molding layer, an underfill layer and a metal layer. Other materials in the lamination surface of the workpiece 20 are within the contemplated scope of disclosure.

The laminating unit 12 may include one or more laminating rollers 12a that may roll over the upper surface of the workpiece stage 11 and the upper surface of the workpiece 20. The laminating roller 12a may contact the adhesive tape 10 as the laminating unit 12 is moved over the upper surface of the workpiece stage 11 and the upper surface of the workpiece 20. Downward pressure may be applied to the laminating roller 12a as the laminating roller 12a roll across the workpiece stage 11 and the workpiece 20. The downward pressure on the laminating roller 12a may press the laminating roller 12a onto the adhesive tape 10, causing the adhesive tape 10 to be securely adhered to the upper surface of the workpiece 20. In at least one embodiment, the laminating unit 12 may be moved and the downward pressure may be applied to the laminating roller 12a manually by an operator. In at least one embodiment, the laminating unit 12 may be moved and the downward pressure may be applied to the laminating roller 12a electronically by an electromechanical device.

As illustrated in FIG. 1A, the photo-treatment device 30 may be configured to perform photo-treatment of the adhesive tape 10 after the adhesive tape 10 is dispensed from the adhesive tape dispenser 102 and before the adhesive tape 10 is laminated on the workpiece 20. In at least one embodiment, the photo-treatment device 30 may be located between the adhesive tape dispenser 102 and the one or more tension bars 6. The photo-treatment device 30 may include a light source 31 and may be configured to perform the photo-treatment of the adhesive tape 10 by treating a portion of the adhesive tape 10 with light from the light source 31. The light source 31 may treat the portion of the adhesive tape 10 as the adhesive tape 10 is being dispensed or during a pause in the dispensing of the adhesive tape 10. The light source 31 may be located on a side of the photo-treatment device 30 that faces the adhesive tape 10. In at least one embodiment, the photo-treatment device 30 may be configured to treat the portion of adhesive tape 10 by exposing the portion of adhesive tape 10 to the light from the light source 31 (i.e., illuminate) for an exposure time in a range from 0.1 second to 1000 seconds. Other exposure times are within the contemplated scope of disclosure.

In at least one embodiment, the light source 31 may include a plate-type light source having a plate shape. Other types and shapes of the light source 31 are within the contemplated scope of disclosure. The light source 31 may include a UV light source that may emit light in the ultraviolet wavelength range. The light source 31 may include, for example, a UV light-emitting diode LED) lamp, a mercury vapor lamp, metal halide lamp, etc. In at least one embodiment, a wavelength of the light from the light source 31 may be in a range from 200 nm to 700 nm. Other wavelengths are within the contemplated scope of disclosure.

As illustrated in FIG. 1A, the photo-treatment device 30 may be separated from the workpiece 20 in the tape advancing direction by a distance D1. In at least one embodiment, the distance D1 between the photo-treatment device 30 (e.g., a photo-treatment location wherein the light source 31 treats the portion of the adhesive tape 10) and the workpiece 20 (e.g., a lamination location where the laminating unit 12 laminates the treated portion of the adhesive tape 10 on the workpiece 20) may be less than 2 meters. Other distances between the photo-treatment device 30 and the workpiece 20 are within the contemplated scope of disclosure.

In at least one embodiment, the light source 31 may be separated (in a direction perpendicular to the surface (e.g., backing surface) of the adhesive tape 10) from the portion of the adhesive tape 10 being treated by a light-to-tape distance D2 in a range from 0.1 cm to 30 cm. Other distances between the light source 31 and the adhesive tape 10 are within the contemplated scope of disclosure.

FIG. 1B is a schematic illustration of the photo-treatment device 30 according to one or more embodiments. As illustrated in FIG. 1B, the light emitted by the light source 30 may irradiate a portion of the adhesive tape 10 to form an irradiated portion 10i (e.g., treated portion) of the adhesive tape 10. The irradiated portion 10i may have a length Lp in the tape advancing direction and a width Wp in a tape width direction perpendicular to the tape advancing direction. The width Wp of the irradiated portion 10i may be less than or equal to a width Wt of the adhesive tape 10. The irradiated portion 10i may have a size and shape corresponding to a size and shape of the light source 31.

As further illustrated in FIG. 1B, the photo-treatment device 30 may include a plurality of control knobs (32, 34, 36, 38) for controlling an operation of (e.g., a setting of) the photo-treatment device 30. In particular, each of the control knobs may control an operating parameter in the photo-treatment of the adhesive tape 10. The photo-treatment device 30 may include a light wavelength control knob 32 for controlling a wavelength of the light emitted by the light source 31. The light wavelength control knob 32 may be turned to adjust the wavelength of the light emitted by the light source 31 to be within a range from 200 nm to 700 nm.

The photo-treatment device 30 may also include a light intensity control knob 34 for controlling an intensity (e.g., in lumens) or power of the light emitted by the light source 31. The light intensity control knob 34 may control an intensity of the light, for example, by controlling an amount of power supplied to the light source 31. The light intensity control knob 34 may be turned to adjust the power supplied to the light source 31 to be within a range from 1 watt to 100 watts.

The photo-treatment device 30 may also include a light exposure time control knob 36 for controlling an exposure time during which the portion of adhesive tape 10 is exposed to the light from the light source 31. The light exposure time control knob 36 may control the exposure time, for example, by controlling the length of time that the light source 31 is activated and emitting light. The light exposure time control knob 36 may be turned to adjust the exposure time to be within a range from 0.1 second to 1000 seconds.

The photo-treatment device 30 may have a fixed or movable position. In at least one embodiment, the photo-treatment device 30 may include a light-to-tape distance control knob 38 for controlling the light-to-tape distance D2 between light source 31 and the adhesive tape 10. The light-to-tape distance control knob 38 may be turned to adjust the light-to-tape distance D2 to be within a range from 0.1 cm to 30 cm. Alternatively, the light-to-tape distance control knob 38 may be omitted and the light-to-tape distance D2 may be adjusted by manually moving the photo-treatment device towards or away from the adhesive tape 10.

In at least one embodiment, where an initial adhesive strength of the adhesive of the adhesive tape 10 is 3.32 N/25 mm, a process fail rate may be 15%. However, where the photo-treatment device 30 is set to have a light wavelength of 400 nm, a light-to-tape distance D2 of 10 cm, and a light power of 5W, an exposure time may be increased (e.g., within about 1 hour) to reduce the adhesive strength from 3.18 N/25 mm to 2.56 N/25 mm so that a process fail rate may be 0%.

FIG. 1C is another schematic illustration of the photo-treatment device 30 according to one or more embodiments. In at least one embodiment, the light source 31 may have a length Ls in the tape advancing direction and a width Ws in the tape width direction. In at least one embodiment, the length Ls of the light source 31 may be less than the width Ws of the light source 31. In at least one embodiment, the width Ws of the light source 31 may be less than or equal to the width Wt of the adhesive tape 10.

In at least one embodiment, the photo-treatment device 30 may be fixed to a wall, ceiling, etc. The photo-treatment device 30 may also include an electromechanical device such as a linear actuator 39 configured to adjust the light-to-tape distance D2. The light source 31 may be mounted on a mounting bracket 41 and the linear actuator 39 may be connected to the mounting bracket 41. Adjusting the light-to-tape distance control knob 38 may activate a motor of the linear actuator 39 causing the linear actuator 39 to move the light source 31 in a direction toward the adhesive tape 10 or in a direction away from the adhesive tape 10. The linear actuator 39 may thus be used to adjust the light-to-tape distance D2 according to the setting of the light-to-tape distance control knob 38.

Adjusting the light-to-tape distance D2 may be used to adjust the size of the irradiated portion 10i of the adhesive tape 10. Increasing the light-to-tape distance D2 may increase the size of the irradiated portion 10i whereas decreasing the light-to-tape distance D2 may decrease the size of the irradiated portion 10i. Adjusting the light-to-tape distance D2 may also be used to adjust the intensity of irradiation by the light from the light source 31. Increasing the light-to-tape distance D2 may decrease the intensity of irradiation whereas decreasing the light-to-tape distance D2 may increase the intensity of irradiation.

In particular, the UV light intensity may follow an inverse-square law, so that the distance between the light source 31 and the adhesive tape 10 decreases, the intensity of UV light on the adhesive tape 10 may increase exponentially. In embodiments in which the light source 31 is closer to the adhesive tape 10, the higher intensity may accelerate the chemical reaction that weakens the adhesive strength. This may result in a quicker and potentially more complete reduction in adhesive strength.

The adhesive tape application system 50 may be used to apply the adhesive tape 10 to the workpiece 20. The workpiece 20 may be cleaned and placed in the workpiece stage 11. The adhesive tape 10 may be pulled to dispense enough of the adhesive tape 10 to be treated by the photo-treatment device 30. The settings of the photo-treatment device 30 may then be adjusted to the proper settings using the control knobs 32, 34, 36, 38 on the photo-treatment device 30. The settings of the photo-treatment device 30 may be adjusted, for example, based on the surface of the workpiece 20 on which the adhesive tape will be applied. The settings of the photo-treatment device 30 may be adjusted based upon other criteria such as photo cross-linker amount in the adhesive of the adhesive tape 10, thickness of the adhesive tape 10, and age of the adhesive tape 10, etc.

The photo-treatment device 30 may be activated to produce an irradiated portion 10i (treated portion) of the adhesive tape 10. The adhesive tape 10 may be pulled so that the irradiated portion 10i is positioned over the workpiece 20. The irradiated portion 10i may then be placed on the workpiece 20 and the laminating unit 12 may be used to press the irradiated portion 10i onto the workpiece 20. The adhesive tape 10 may be cut around the perimeter of the workpiece 20. Alternatively, the adhesive tape 10 may be precut (e.g., perforated) to have a size and shape that substantially matches the size and shape of the workpiece 20, in which case no cutting may be necessary after the lamination process is performed. The workpiece 20 including the laminated adhesive tape 10 may then be removed from the workpiece stage 11.

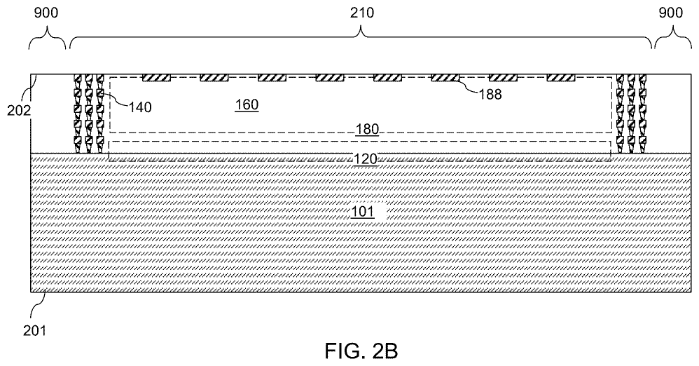

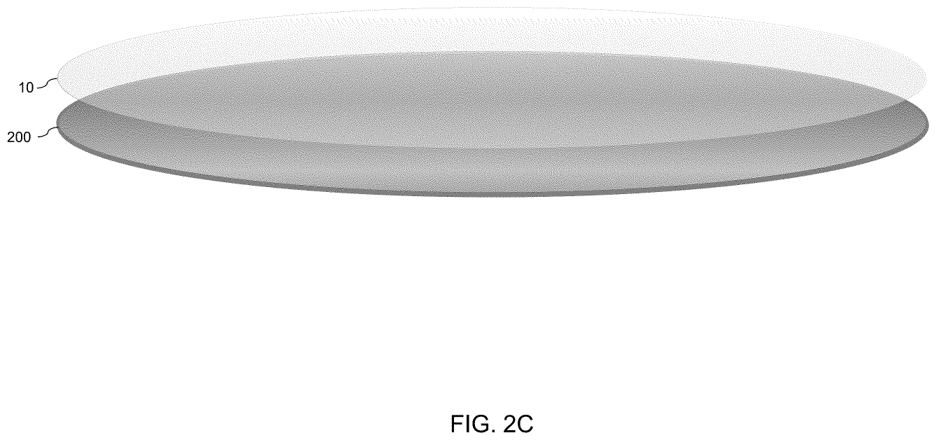

FIG. 2A is a top-down view of a semiconductor wafer 100 that may be a workpiece 20 in the adhesive tape application system 50 according to one or more embodiments. The semiconductor wafer 100 may include a plurality of semiconductor devices and metal interconnect structures formed within dielectric material layers over a semiconductor substrate.

As illustrated in FIG. 2A, the semiconductor wafer may include a two-dimensional array of semiconductor die regions 210 and dicing channel region 900. The semiconductor die regions 210 may include rectangular portions of the semiconductor wafer 100 that become semiconductor dies upon dicing of the semiconductor wafer 100 in a subsequent processing step. The dicing channel regions 900 may include grid-shaped portions of the semiconductor wafer 100 that are removed during the dicing of the semiconductor wafer 100.

FIG. 2B is a vertical cross-sectional view of a region of the semiconductor wafer 100 along the vertical plane B-B′ of FIG. 2A, according to one or more embodiments. As illustrated in FIG. 2B, the semiconductor wafer 100 may include a semiconductor substrate 101 that may include a commercially available semiconductor wafer such as a single crystalline wafer. The semiconductor wafer 100 may include a first side 201 and a second side 202, either of which may serve as a surface on which the adhesive tape 10 may be applied by the adhesive tape application system 50.

Semiconductor devices 120 may be formed on the semiconductor substrate 101 within each area of the semiconductor die regions 210. The semiconductor devices 120 may include any type of semiconductor devices known in the art such as field effect transistors, capacitors, resistors, inductors, diodes, etc. Metal interconnect structures 180 may be formed within dielectric material layers 160 that may be subsequently formed over the semiconductor devices 120. The metal interconnect structures 180 may provide electrical connections to and from the semiconductor devices 120 and die bump structures to be subsequently formed. The metal interconnect structures 180 may include various metal lines, metal via structures, etc. The metal interconnect structures 180 may include copper-based metal interconnect structures and/or aluminum-based metal interconnect structures. The metal interconnect structures 180 may include bonding pads 188. The dielectric material layers 160 may include, for example, inorganic dielectric materials such as silicate glasses, silicon nitride, silicon carbide nitride, silicon oxynitride, dielectric metal oxides, etc.

A frame-shaped peripheral portion within each semiconductor die region 210 comprises an edge-seal region that contains an edge-seal structure 140. The frame-shaped peripheral portion is herein referred to as a seal ring region. The edge-seal structure 140 comprises at least one continuous set of metal interconnect structures that vertically extends from the top surface of the semiconductor substrate 101 to the topmost surface of the dielectric material layers 160.

FIG. 2C is an exploded view of the semiconductor wafer 100 including the irradiated portion 10i of adhesive tape 10 according to one or more embodiments. After the adhesive tape 10 is laminated on the semiconductor wafer 100 (e.g., workpiece 20 in FIG. 1A) using the adhesive tape application system 50, the adhesive tape 10 may be cut around the outer perimeter of the semiconductor wafer 100. The adhesive tape 10 may be cut manually with a cutting knife, or by an electromechanical cutting tool. Alternatively, the adhesive tape 10 may be precut (e.g., perforated) to have a size and shape that substantially matches the size and shape of the workpiece 20, in which case no cutting may be necessary after the lamination process is performed. In at least one embodiment, an outer perimeter of the adhesive tape 10 may be substantially aligned with the outer perimeter of the semiconductor wafer.

A thickness of the adhesive tape 10 may depend upon the type of adhesive tape 10. In particular, in embodiments in which the adhesive tape 10 is dicing tape, the thickness of the adhesive tape 10 may be in a range from 70 μm to 150 μm. In embodiments in which the adhesive tape 10 is back grinding (BG) tape, the thickness of the adhesive tape 10 may be in a range from 200 μm to 300 μm. The semiconductor wafer 100 may have a thickness in a range from 100 μm to 800 μm depending upon the type and size (e.g., diameter) of the semiconductor wafer 100.

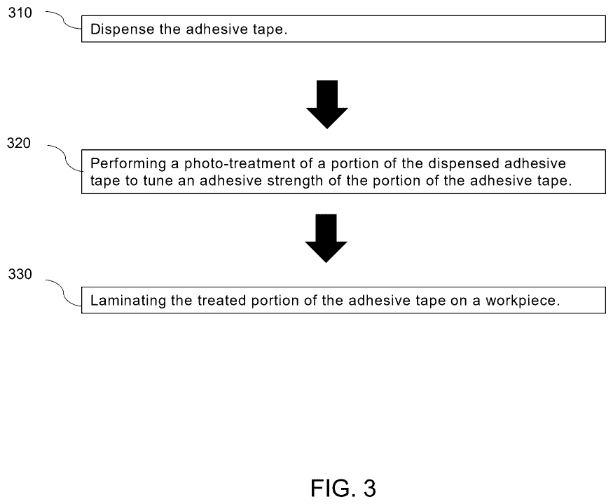

FIG. 3 is a flowchart illustrating a method of applying adhesive tape to a workpiece according to one or more embodiments. Step 310 of the method may include dispensing the adhesive tape. Step 320 may include performing photo-treatment of a portion of the dispensed adhesive tape to tune an adhesive strength of the portion of the adhesive tape. Step 330 may include laminating the treated portion of the adhesive tape on a workpiece.

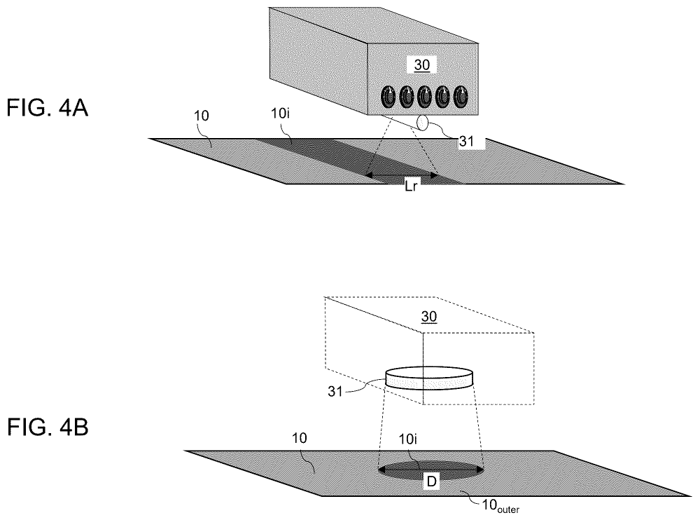

FIGS. 4A and 4B are schematic illustrations of a photo-treatment device 30 having alternative configurations according to one or more embodiments. FIG. 4A is a schematic illustration of a photo-treatment device 30 having a first alternative configuration according to one or more embodiments. As illustrated in FIG. 4A, the photo-treatment device 30 having the first alternative configuration may be substantially similar to the photo-treatment device 30 in FIGS. 1A-1C. However, the light source 31 in the photo-treatment device 30 having the first alternative configuration may include a rod-type light source. The rod-type light source may have a substantially circular cylindrical shape extending lengthwise in the tape width direction. Light from the rod-type light source may irradiate a portion of the adhesive tape 10 to form an irradiated portion 10i. The irradiated portion 10i may have a length Lr in a tape advancing direction. The length Lr of the irradiated portion 10i formed by the rod-type light source may be less than the length Lp of the irradiated portion 10i formed by the plate-type light source (see FIGS. 1B and 1C).

FIG. 4B is a schematic illustration of a photo-treatment device 30 having a second alternative configuration according to one or more embodiments. The photo-treatment device 30 is shown in FIG. 4B with transparent sides in order to illustrate the light source 31. The control knobs on the photo-treatment device 30 (e.g., knobs 32-38) are also omitted in order to illustrate the light source 31.

As illustrated in FIG. 4B, the photo-treatment device 30 having the second alternative configuration may be substantially similar to the photo-treatment device 30 in FIGS. 1A-1C and the photo-treatment device 30 having the first alternative configuration in in FIG. 4A. However, the light source 31 in the photo-treatment device 30 having the second alternative configuration may include a circular-shaped light source. The circular shaped light source may have a substantially circular shape. The circular-shaped light source may have a size and shape corresponding to a size and shape of the workpiece 20 (e.g., 8-inch diameter semiconductor wafer, 12 inch diameter semiconductor wafer, etc.).

As further illustrated in FIG. 4B, light from the circular-shaped light source may irradiate a portion of the adhesive tape 10 to form a circular-shaped irradiated portion 10i. The irradiated portion 10i may have a diameter D which may be greater than a diameter of the workpiece 20. In particular, the diameter D may greater than 8 inches, greater than 12 inches, etc. depending upon the size of the workpiece 20. The irradiated portion 10i may also be located in a central portion of the adhesive sheet 10 in a tape width direction. An outer portion 10ₒᵤₜₑᵣ of the adhesive tape 10 may not be irradiated by the light from the circular-shaped light source. The location of the irradiated portion 10i of the adhesive tape 10 in the central portion of the adhesive tape 10 may substantially correspond to a location of the workpiece 20 in the adhesive tape application system 50.

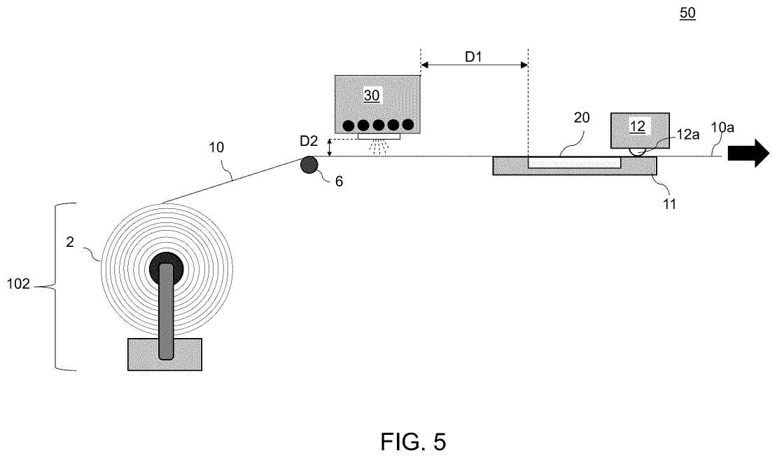

FIG. 5 is a schematic illustration of the adhesive tape application system 50 having a first alternative configuration. As illustrated in FIG. 5, the adhesive tape application system 50 having the first alternative configuration may be substantially the same as the adhesive tape application system 50 in FIG. 1A. However, in the adhesive tape application system 50 having the first alternative configuration, the photo-treatment device 30 may have a different location. In particular, the photo-treatment device 30 may be located not between the adhesive tape dispenser 102 and the tension bar 6, but between the tension bar 6 and the workpiece 20.

As with the photo-treatment device 30 in FIG. 1A, the photo-treatment device 30 in the first alternative configuration may be separated from the workpiece 20 in the tape advancing direction by a distance D1 that is less than 2 meters. Further, as with the photo-treatment device 30 in FIG. 1A, the light source 31 of the photo-treatment device 30 may be separated from the portion of the adhesive tape 10 being treated by a light-to-tape distance D2 in a range from 0.1 cm to 30 cm. It should be noted that in both the photo-treatment device 30 in FIG. 1A and the photo-treatment device 30 having the first alternative configuration in FIG. 5, the photo-treatment device 30 may be located beneath the adhesive tape 10 instead of above the adhesive tape 10.

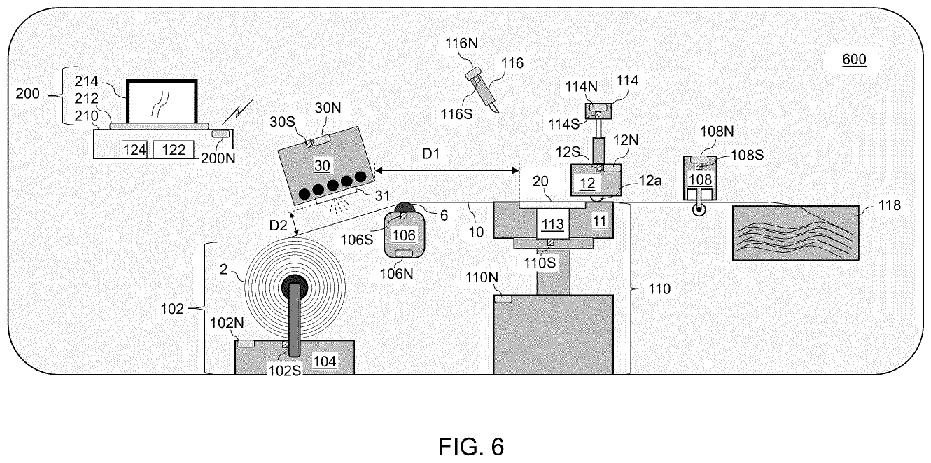

FIG. 6 is a schematic illustration of an adhesive tape application system 600 according to one or more embodiments. As illustrated in FIG. 6, the adhesive tape application system 600 may be substantially the same as the adhesive tape application system 50 in FIG. 1A and the adhesive tape application system 50 having the first alternative configuration in FIG. 5. However, the adhesive tape application system 600 may include a substantially automated system, requiring minimal to no operator intervention. In particular, the adhesive tape application system 600 may utilize one or more electromechanical devices to apply the adhesive tape 10 to the workpiece 20 such as a semiconductor wafer. The adhesive tape application system 600 may also include a control unit for controlling an operation of (e.g., a setting of) the electromechanical devices in the adhesive tape application system 600. The adhesive tape application system 600 may, therefore, ensure consistency and accuracy, which may be desirable in protecting and handling delicate wafers during processes such as back grinding, dicing, or wafer mounting.

As illustrated in FIG. 6, the adhesive tape application system 600, may include an adhesive tape dispenser 102. The adhesive tape dispenser 102 may include the tape supply roll 102. The tape supply roll 102 may hold the adhesive tape 10 (e.g., dicing tape, back grinding tape, etc.) to be applied to the workpiece 20. The tape supply roll 102 may feed the adhesive tape 10 into the adhesive tape application system 600. The tape supply roll 102 may handle the adhesive tape 10 in a way that mitigates contamination or damage to the adhesive surface.

The adhesive tape dispenser 102 may also include an unwinding mechanism 104 connected to the tape supply roll 102. The unwinding mechanism 104 may control an unwinding of the adhesive tape 10 from the tape supply roll 102. The unwinding mechanism 104 may help to ensure smooth, tension-controlled feeding of the adhesive tape 10 into a tape application area around the workpiece 20. The unwinding mechanism 104 may help to prevent wrinkles, stretching, or slack that may affect the quality of the adhesive tape 10 application.

The adhesive tape dispenser 102 may include an electromechanical device that may be controlled by the control unit 200. In particular, the unwinding mechanism 104 of the adhesive tape dispenser 102 may be controlled by the control unit 200. The adhesive tape dispenser 102 may include a mechanism for rotating the tape supply roll 2 and one or more tape dispenser sensors 102S for detecting a rotational speed of the tape supply roll 102 (e.g., a speed at which the adhesive tape 10 is dispensed from the tape supply roll 2). The tape dispenser sensors 102S may detect a condition/status of the adhesive tape dispenser 102 and feed the results back to the control unit 200. The tape dispenser sensors 102S may also detect (e.g., by optical inspection) a result of an operation of the adhesive tape dispenser 102 (e.g., to determine whether there is too little or not enough slack in the adhesive tape 10) and feed the results back to the control unit 200. The control unit 200 may adjust an operation of (e.g., a setting of) the unwinding mechanism 104 based on the feedback from the tape dispenser sensors 102S. The adhesive tape dispenser 102 may also include a network interface module 102N (e.g., wireless network adapter, ethernet adapter, etc.) configured to communicatively couple (e.g., via ethernet cable or wireless link such as Wi-Fi, Bluetooth®, etc.) the adhesive tape dispenser 102 to the control unit 200.

The adhesive tape application system 600 may also include a tension control unit 106. The tension control unit 106 may include the tension bar 6 in contact with the adhesive tape 10. The tension control unit 106 may include a mechanism (e.g., linear actuator) for moving the tension bar 6 to maintain a proper tension on the adhesive tape 10. The tension control unit 106 may monitor and maintain consistent adhesive tape 10 tension throughout the application process. Proper adhesive tape 10 tension may be desired to ensure a smooth, even application of the adhesive tape 10 without creases or bubbles. Proper adhesive tape 10 tension may also prevent excessive stretching or tearing of the adhesive tape 10 during unwinding and lamination.

The tension control unit 106 may include an electromechanical device that may be controlled by the control unit 200. In particular, the position of the one or more tension bars 6 may be controlled by the control unit 200. The tension control unit 106 may include a mechanism for moving the tension bar 6 and one or more tension control sensors 106S (e.g., pressure sensors) for detecting an amount of pressure placed on the tension bar 6 by the adhesive tape 10. The tension control sensors 106S may detect a condition/status of the tension control unit 106 and feed the results back to the control unit 200. The tension control sensors 106S may detect (e.g., by optical inspection) a result of an operation of the tension control unit 106 (e.g., to determine if there is excess slack in the adhesive tape 10) and feed the results back to the control unit 200. The control unit 200 may adjust an operation of (e.g., a setting of) the tension control unit 106 based on the feedback from the tension control sensors 106S. The tension control unit 106 may also include a network interface module 106N (e.g., wireless network adapter, ethernet adapter, etc.) configured to communicatively couple (e.g., via ethernet cable or wireless link such as Wi-Fi, Bluetooth®, etc.) the tension control unit 106 to the control unit 200.

The adhesive tape application system 600 may also include an alignment and positioning unit 108. The alignment and positioning unit 108 may precisely align the adhesive tape 10 relative to a surface of the workpiece 20 before application of the adhesive tape 10. The alignment and positioning unit 108 may help to ensure accurate placement of the adhesive tape 10 over the workpiece 20. The alignment and positioning unit 108 may include one or more sensors or cameras to detect a position of the workpiece 20 and adjust the adhesive tape 10 to the correct alignment for optimal coverage, preventing misalignment or edge overlap.

The alignment and positioning unit 108 may include an electromechanical device that is controlled by the control unit 200. In particular, the movement of the alignment and positioning unit 108 may be controlled by the control unit 200. The alignment and positioning unit 108 may include a clamping mechanism for clamping down on the adhesive tape 10 and a mechanism for moving the adhesive tape 10 into proper position and alignment. The alignment and positioning unit 108 may also include one or more alignment and position sensors 108S (e.g., image capture devices) for detecting a position of the adhesive tape 10 and determining if the adhesive tape 10 is in or out of proper alignment. The alignment and position sensors 108S may detect a condition/status of the alignment and positioning unit 108 and feed the results back to the control unit 200. The alignment and position sensors 108S may also detect (e.g., by optical inspection) a result of an operation of the alignment and positioning unit 108 (e.g., to determine whether there is a misalignment or mispositioning of the adhesive tape 10) and feed the results back to the control unit 200. The control unit 200 may adjust an operation of (e.g., a setting of) the alignment and positioning unit 108 based on the feedback from the alignment and position sensors 108S. The alignment and positioning unit 108 may also include a network interface module 108N (e.g., wireless network adapter, ethernet adapter, etc.) configured to communicatively couple (e.g., via ethernet cable or wireless link such as Wi-Fi, Bluetooth®, etc.) the alignment and positioning unit 108 to the control unit 200.

The adhesive tape application system 600 may also include a workpiece handling unit 110. The workpiece handling unit 110 may include, for example, the workpiece stage 11 (e.g., chuck table) and a workpiece carrier 113 (e.g., vacuum chuck). The workpiece stage 11 may securely hold the workpiece 20 in place during the tape application process, usually through vacuum suction or mechanical clamps. The workpiece 20 may be firmly positioned without shifting to ensure uniform application of the adhesive tape 10. The workpiece handling unit 110 may help to prevent damage to the workpiece 20 and may help to ensure that the adhesive tape 10 is applied smoothly across an upper surface of the workpiece 20.

The workpiece carrier 113 may hold the workpiece 20 (e.g., through vacuum suction) firmly during transport within the adhesive tape application system 600. The workpiece carrier 113 may help to ensure stability of the workpiece 20 and may mitigate against movement of the workpiece 20 during the adhesive tape application process, especially as the workpiece 20 moves through different stages like alignment, lamination, and cutting of the adhesive tape 10.

The workpiece handling unit 110 may include an electromechanical device that may be controlled by the control unit 200. In particular, the movement of the workpiece carrier 113 may be controlled by the control unit 200. The workpiece carrier 113 may include a transport mechanism for moving the workpiece 20 and a clamping mechanism (e.g., vacuum suction) for securely holding the workpiece 20 during transport. The workpiece handling unit 110 may also include one or more workpiece handling sensors 110S for detecting a position of the workpiece carrier 113 and detecting whether the workpiece carrier 113 has a secure hold of the workpiece 20. The workpiece handling sensors 110S may detect a condition/status of the workpiece handling unit 110 and feed the results back to the control unit 200. The workpiece handling sensors 110S may also detect (e.g., by optical inspection) a result of an operation of the workpiece carrier 110 (e.g., to determine if there is a mishandling of the workpiece 20) and feed the results back to the control unit 200. The control unit 200 may adjust an operation of (e.g., a setting of) the workpiece carrier 113 based on the feedback from the workpiece handling sensors 110S. The workpiece handling unit 110 may also include a network interface module 110N (e.g., wireless network adapter, ethernet adapter, etc.) configured to communicatively couple (e.g., via ethernet cable or wireless link such as Wi-Fi, Bluetooth®, etc.) the workpiece handling unit 110 to the control unit 200.

The adhesive tape application system 600 may also include the laminating unit 12 including the laminating roller 12a or a laminating plate press. The laminating unit 12 may apply the adhesive tape 10 to the upper surface of the workpiece 20 with controlled pressure. The laminating unit 12 may help to ensure that the adhesive tape 10 bonds smoothly to the upper surface of the workpiece 20 without trapping air bubbles or creating wrinkles. A pressure, speed, and angle of the laminating unit 12 may be carefully regulated to optimize adhesion and protect the upper surface of the workpiece 20.

The laminating unit 12 may include an electromechanical device that is controlled by the control unit 200. In particular, the movement of the laminating unit 12 may be controlled by the control unit 200. The laminating unit 12 may include one or more laminating position sensors 12S for detecting a position of the laminating unit 12. The laminating position sensors 12S may detect a condition/status of the laminating unit 12 and feed the results back to the control unit 200. The laminating position sensors 12S may also detect (e.g., by optical inspection) a result of an operation of the laminating unit 12 (e.g., to determine if there is a mispositioning of the laminating unit 12) and feed the results back to the control unit 200. The control unit 200 may adjust an operation of (e.g., a setting of) the laminating unit 12 based on the feedback from the laminating position sensors 12S. The laminating unit 12 may also include a network interface module 12N (e.g., wireless network adapter, ethernet adapter, etc.) configured to communicatively couple (e.g., via ethernet cable or wireless link such as Wi-Fi, Bluetooth®, etc.) the laminating unit 12 to the control unit 200.

The adhesive tape application system 600 may also include a pressure adjusting unit 114 connected to the laminating unit 12. The pressure adjusting unit 114 may allow fine-tuning of pressure applied to the adhesive tape 10 by the laminating unit 12 during a laminating process. In at least one embodiment, different processes may require different lamination pressures. For example, lower pressure might be applied where the workpiece 20 is a delicate semiconductor wafer to avoid stress or warping, while higher pressure may be applied where the workpiece 20 is a robust semiconductor wafer and/or where the adhesive tape 10 has a relatively high thickness.

The pressure adjusting unit 114 may include an electromechanical device that is controlled by the control unit 200. In particular, the laminating pressure applied to the adhesive tape 10 by the roller 12a may be adjusted by the pressure adjusting unit 114 under the control of the control unit 200. The pressure adjusting unit 114 may include one or more laminating pressure sensors 114S (e.g., pressure sensors) for detecting the pressure applied to the adhesive tape 10 by the roller 12a. The laminating pressure sensors 114S may detect a condition/status of the pressure adjusting unit 114 and feed the results back to the control unit 200. The laminating pressure sensors 114S may also detect (e.g., by optical inspection) a result of an operation of the pressure adjusting unit 114 (e.g., to determine if the pressure is insufficient or excessive) and feed the results back to the control unit 200. The control unit 200 may adjust an operation of (e.g., a setting of) the pressure adjusting unit 114 based on the feedback from the laminating pressure sensors 114S. The pressure adjusting unit 114 may also include a network interface module 114N (e.g., wireless network adapter, ethernet adapter, etc.) configured to communicatively couple (e.g., via ethernet cable or wireless link such as Wi-Fi, Bluetooth®, etc.) the pressure adjusting unit 114 to the control unit 200.

The adhesive tape application system 600 may also include an electromechanical cutting tool 116. The cutting tool 116 may cut the adhesive tape 10 around the perimeter of the workpiece 20 after the adhesive tape 10 has been laminated on the workpiece 20. The cutting tool 116 may help to ensure that the adhesive tape 10 is cut cleanly and precisely along an edge of the workpiece 20 or according to specific dimensions. The cutting tool 116 may include, for example, a blade or laser (e.g., CO2 laser) that provides clean, residue-free cuts.

The cutting tool 116 may include an electromechanical device that is controlled by the control unit 200. In particular, the precise location of the cutting tool 116 and the pressure applied to the adhesive tape 10 by the cutting tool 116 may be controlled by the control unit 200. The cutting tool 116 may include one or more cutting sensors 116S for detecting a location of the cutting tool 116 and detecting the pressure applied to the adhesive tape 10 by the cutting tool 116. The cutting tool sensors 116S may detect a condition/status of the cutting tool 116 and feed the results back to the control unit 200. The cutting tool sensors 116S may also detect (e.g., by optical inspection) a result of an operation of the cutting tool 116 (e.g., to determine a precision of the cut) and feed the results back to the control unit 200. The control unit 200 may adjust an operation of (e.g., a setting of) the cutting tool 116 based on the feedback from the cutting tool sensors 116S. The cutting tool 116 may also include a network interface module 116N (e.g., wireless network adapter, ethernet adapter, etc.) configured to communicatively couple (e.g., via ethernet cable or wireless link such as Wi-Fi, Bluetooth®, etc.) the cutting tool 116 to the control unit 200.

The adhesive tape application system 600 may also include one or more additional sensors and cameras (not shown) for detecting one or more operating conditions of adhesive tape application system 600. The sensors and cameras may monitor the position, alignment, and condition of the workpiece 20 and/or the adhesive tape 10. The sensors and cameras may provide real-time feedback to ensure accurate application, detect misalignment, or flag defects such as bubbles or wrinkles in the tape.

The adhesive tape application system 600 may also include a waste collection unit 118. The waste collection unit 118 may collect and dispose of the tape backing or unused tape after application of the adhesive tape 10. Once the adhesive tape 10 is applied to the workpiece 20, the non-adhesive liner (if present) or excess tape may be wound onto a take-up roll or collected in a waste bin for easy disposal, keeping the work area clean and ensuring efficient operation.

The adhesive tape application system 600 may also include the photo-treatment device 30 between the adhesive tape dispenser 102 and the laminating unit 12. The photo-treatment device 30 may perform photo-treatment of the adhesive tape 10 to tune an adhesive strength of the adhesive tape 10 under the control of the control unit 200. In at least one embodiment, the operating parameters for the photo-treatment process may be input into the control unit 200 and transmitted to the photo-treatment device 30. The photo-treatment device 30 may then adjust the operating parameters and perform the photo-treatment process accordingly. The operating parameters may include, for example, a wavelength of the light emitted by the light source 31, an intensity (e.g., in lumens) of the light emitted by the light source 31, an exposure time during which the portion of adhesive tape 10 is exposed to the light from the light source 31, and the light-to-tape distance D2 between light source 31 and the adhesive tape 10.

The photo-treatment device 30 may include one or more photo-treatment sensors 30S for detecting various operating conditions of the photo-treatment device 30. The photo-treatment sensors 30S may detect a condition/status of the photo-treatment device 30 and feed the results back to the control unit 200. The photo-treatment sensors 30S may also detect (e.g., by optical inspection) a result of an operation of the photo-treatment device 30 (e.g., to determine a size and location of the irradiated portion 10i of the adhesive tape 10) and feed the results back to the control unit 200. The control unit 200 may adjust an operation of (e.g., a setting of) the photo-treatment device 30 based on the feedback from the photo-treatment sensors 30S. The photo-treatment device 30 may also include a network interface module 30N (e.g., wireless network adapter, ethernet adapter, etc.) configured to communicatively couple (e.g., via ethernet cable or wireless link such as Wi-Fi, Bluetooth®, etc.) the photo-treatment device 30 to the control unit 200.

The control unit 200 may manage and overall operation of the adhesive tape application system 600, including, for example, feeding of the adhesive tape 10, tension control of the adhesive tape 10, alignment of the adhesive tape 10 with the workpiece 20, lamination of the workpiece 20, and cutting of the adhesive tape 10. The control unit 200 may include a computer 210 such as a desktop computer, laptop computer, server, mainframe, etc. The computer 210 may include one or more memory devices 124 (e.g., storage disk, random access memory (RAM), read-only memory (ROM), etc.) for storing software, data, instructions, etc. The computer 210 may also include one or more processors 122 (e.g., central processing unit (CPU)) that may execute the instructions to perform tasks such as storing, manipulating and processing data.

In at least one embodiment, the computer 210 may also include a video card for generating display data that may produce a user interface, render graphics, etc. The computer 210 may also include a network interface card (NIC) for allowing the computer 210 to communicate with other units and devices (e.g., other elements of the adhesive tape application system 600) over a local area network or the Internet. The computer 210 may also include a network interface module 200N (e.g., wireless network adapter, ethernet adapter, etc.) for transmitting signals to and receiving signals from (e.g., via ethernet cable or via Wi-Fi, Bluetooth® or other wireless protocol) the other elements of the adhesive tape application system 600.

The control unit 200 may also include an input device 212 such as a keyboard, mouse, touchpad, etc. that may be used to input instructions, data, etc. into the computer 210. The control unit 200 may also include a display device 214 such as a liquid crystal display (LCD) device, cathode ray tube (CRT) display device, light-emitting diode (LED) display device, etc. The display device 214 may display video and graphics information generated by the video card of the computer 210.

The control unit 200 may additionally or alternatively include a programmable logic controller (PLC) (not shown). The PLC may include an industrial digital computer used to control manufacturing processes, machinery, or robotic devices in real-time. The PLC may be programmed to execute specific tasks, such as turning on or off certain parts of a machine, based on input from sensors or operator commands.

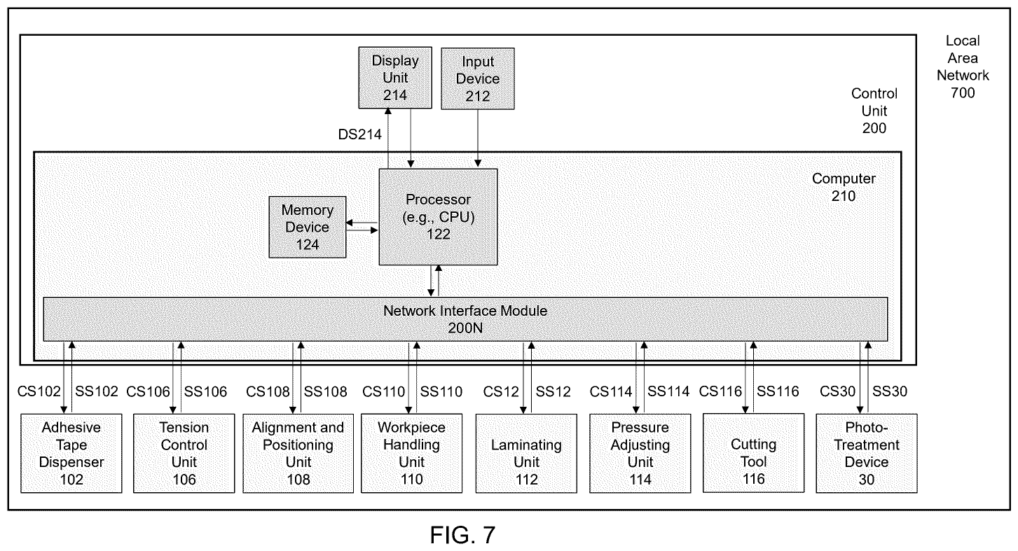

FIG. 7 is a schematic block diagram of the control unit 200 according to one or more embodiments. The various elements of the adhesive tape application system 600 (see FIG. 6) including the adhesive tape dispenser 102, tension control unit 106, alignment and positioning unit 108, workpiece handling unit 110, laminating unit 112, pressure adjustment unit 114, cutting tool 116 and photo-treatment device 30, may be communicatively coupled to the control unit 200 as part of a local area network 700. The various elements of the adhesive tape application system 600 may be connected to the control unit 200 by a wired connection (e.g., ethernet cable) or by a wireless connection (e.g., via Wi-Fi, Bluetooth® or other wireless protocol).

In at least one embodiment, the adhesive tape dispenser 102 may transmit a status/feedback signal SS102 including status information and/or feedback information for the adhesive tape dispenser 102 to the computer 210 through the network interface module 200N. The computer 210 may transmit a control signal CS102 to the adhesive tape dispenser 102 for controlling an operation of the adhesive tape dispenser 102. The tension control unit 106 may transmit a status/feedback signal SS106 including status information and/or feedback information for the tension control unit 106 to the computer 210 through the network interface module 200N. The computer 210 may transmit a control signal CS106 to the tension control unit 106 for controlling an operation of the tension control unit 106. The alignment and positioning unit 108 may transmit a status/feedback signal SS108 including status information and/or feedback information for the alignment and positioning unit 108 to the computer 210 through the network interface module 200N. The computer 210 may transmit a control signal CS108 to the alignment and positioning unit 108 for controlling an operation of the alignment and positioning unit 108. The workpiece handling unit 110 may transmit a status/feedback signal SS110 including status information and/or feedback information for the workpiece handling unit 110 to the computer 210 through the network interface module 200N. The computer 210 may transmit a control signal CS110 to the workpiece handling unit 110 for controlling an operation of the workpiece handling unit 110. The laminating unit 12 may transmit a status/feedback signal SS12 including status information and/or feedback information for the laminating unit 12 to the computer 210 through the network interface module 200N. The computer 210 may transmit a control signal CS12 to the laminating unit 12 for controlling an operation of the laminating unit 12. The pressure adjusting unit 114 may transmit a status/feedback signal SS114 including status information and/or feedback information for the pressure adjusting unit 114 to the computer 210 through the network interface module 200N. The computer 210 may transmit a control signal CS114 to the pressure adjusting unit 114 for controlling an operation of the pressure adjusting unit 114. The cutting tool 116 may transmit a status/feedback signal SS116 including status information and/or feedback information for the cutting tool 116 to the computer 210 through the network interface module 200N. The computer 210 may transmit a control signal CS116 to the cutting tool 116 for controlling an operation of the cutting tool 116. The photo-treatment device 30 may transmit a status/feedback signal SS30 including status information and/or feedback information for the photo-treatment device 30 to the computer 210 through the network interface module 200N. The computer 210 may transmit a control signal CS30 to the photo-treatment device for controlling an operation of the photo-treatment device 30.

The network interface module 200N of the computer 210 may transmit data from the status/feedback signals of the various elements of the adhesive tape application system 600 (e.g., SS102, SS106, SS108, SS110, SS12, SS114, SS116 and SS30) to the processor 122. The processor 122 may perform one or more operations on the data to determine an operating condition of the various elements. In at least one embodiment the processor 122 may compare the data to reference data to determine if the various elements are operating properly. The processor 122 may transmit control signals for controlling the various elements of the adhesive tape application system 600 (e.g., CS102, CS106, CS108, CS110, CS12, CS114, CS116 and CS30) based on the data in the status/feedback signals from the various elements of the adhesive tape application system 600.

The processor 122 may access the memory device 124 to store the data from the status/feedback signals (e.g., SS102, SS106, SS108, SS110, SS12, SS114, SS116 and SS30). In at least one embodiment, the memory device 124 may store other data such as history data, reference data, etc. that may be accessed by the processor 122. The memory device 124 may also store data and/or instructions in the form of a lookup table and/or a calculation table. These tables may be accessed by the processor 122 and used by the processor 122 to execute instructions or control various operations in the adhesive tape application system 600.

The processor 122 may also be connected to an operator control signal line for controlling an operation of the processor 122. An operator (e.g., user) may use the input device 212 to input an operating instruction over the operator control signal line to the processor 122. The operator may also input software updates, adjust an operating condition, etc. over the operator control signal line.

The processor 122 may also transmit one or more display signals DS214 to the display device 214. The display device 214 may generate one or more display screens based on the display signals DS214. In particular, the display device 214 may display a graphical user interface (GUI) that may allow the operator to interface with the control unit 200. The GUI may display data pertaining to the operation of the various elements of the adhesive tape application system 600. The GUI may also include icons, menus, buttons, etc. allowing the operator to input data and instructions for participating in control of the adhesive tape application system 600. In at least one embodiment, the display device 214 may include a touch screen and the operator viewing the GUI may use the touch screen of the display device 214 to transmit data and/or instructions to the processor 122. In at least one embodiment, the operator may use the GUI to input operating parameters to the various elements of the adhesive tape application system 600 such as adhesive tape type, workpiece size (e.g., wafer size), laminating roller pressure settings, etc. In particular, the operator may use the GUI to input operating parameters of the photo-treatment device 30 including a wavelength of the light emitted by the light source 31, an intensity of the light emitted by the light source 31, exposure time during which the portion of adhesive tape 10 is exposed to the light from the light source 31, and the light-to-tape distance D2 between light source 31 and the adhesive tape 10.

An adhesive tape application process using the adhesive tape application system 600 may be initiated by an operator using the GUI displayed on the display device 214 of the control unit 200. The GUI may allow the operator to select a semiconductor wafer (e.g., workpiece 20) to be used in the adhesive tape application process. The workpiece handling unit 110 may cause the selected semiconductor wafer to be carried into position to be laminated by the laminating unit 12.

Data on the materials of the surface of the selected semiconductor wafer may be stored, for example, in the memory device 124. The processor 122 may access the data in the memory device 124 and cause the GUI to display the data. In particular, the GUI may indicate that the surface of semiconductor wafer includes silicon, copper, molding material, etc. The memory device 124 may also store one or more look-up tables including recommended adhesive strengths for various materials of a workpiece surface. The processor 122 may access the look-up tables and cause the GUI to display the recommended adhesive strength for an adhesive tape to be applied to the selected semiconductor wafer.

A tape supply roll 102 of adhesive tape 10 may be previously installed in the adhesive tape application system 600. Characteristic data on the characteristics of the adhesive tape 10 on the tape supply roll 102 (e.g., data from the CoA, tested adhesive strength (e.g., tape initial state measurement), age of the adhesive tape, etc.) may also be stored in the memory device 124. The processor 122 may access the characteristic data in the memory device 124 and cause the characteristic data to be displayed in the GUI on the display device 214.

The memory device 124 may also include a software program for determining a photo-treatment protocol to arrive at a recommended adhesive strength based on characteristic data of adhesive tape. The processor 122 may execute the instructions of the software program to determine a photo-treatment protocol for the adhesive tape 10 on the tape supply roll 102 and cause the GUI to display the determined photo-treatment protocol. In particular, the determined photo-treatment protocol may include recommended settings for various operating parameters for the photo-treatment device 30 including, for example, a wavelength of the light emitted by the light source 31, an intensity (e.g., in lumens) of the light emitted by the light source 31, an exposure time during which the portion of adhesive tape 10 is exposed to the light from the light source 31, and the light-to-tape distance D2 between light source 31 and the adhesive tape 10. The processor 122 may also be programmed to recommend settings of operating parameters of other elements of the adhesive tape application system 600 (e.g., recommended laminating pressure) and display those recommended settings in the GUI on the display device 214. The operator may then input an acceptance of the recommended settings for the operating parameters of the photo-treatment device 30 and recommended settings of the other elements of the adhesive tape application system 600 using the GUI on the display device 214. The operator's acceptance may cause the processor 122 to transmit a control signal CS 30 to the photo-treatment device 30 to set the operating parameters to the recommended settings.

The adhesive tape application process may then proceed in the adhesive tape application system 600. The adhesive tape dispenser 102 may dispense an appropriate length of the adhesive tape 10, while the alignment and positioning unit 108 pulls on the adhesive tape 10 in the tape advancing direction and the tension control unit 106 maintains a proper amount of tension on the adhesive tape 10. The dispensing of the adhesive tape 10 may then be paused while the photo-treatment device 30, having been set to the recommended settings, performs photo-treatment of a portion of the adhesive tape 10 to tune the adhesive strength of the treated portion to the recommended adhesive strength. After the photo-treatment is complete, the dispensing of the adhesive tape 10, pulling on the adhesive tape 10 and tension control of adhesive tape 10 may continue until the irradiated portion 10i (treated portion) of the adhesive tape 10 is positioned over the semiconductor wafer.

The alignment and positioning unit 108 may then lower the adhesive tape 10 onto the semiconductor wafer. The laminating unit 12 may then laminate the adhesive tape 10 onto the semiconductor wafer. After the lamination process is completed, the cutting tool 116 may automatically cut the adhesive tape 10 around the perimeter of the semiconductor wafer. Alternatively, the adhesive tape 10 may be precut (e.g., perforated) to have a size and shape that substantially matches the size and shape of the workpiece 20, in which case no cutting may be necessary after the lamination process is performed. The wafer handling unit 110 may then cause the semiconductor wafer to be carried out of the adhesive tape application system 600 and present the semiconductor wafer to the operator for visual inspection and further processing.

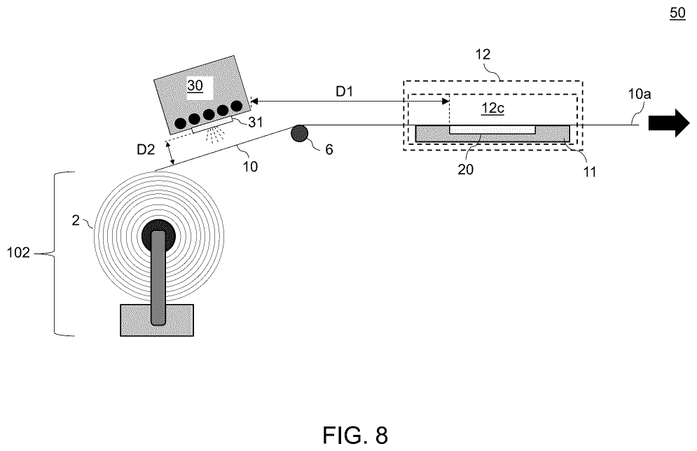

FIG. 8 is a schematic illustration of the adhesive tape application system 50 having a second alternative configuration. As illustrated in FIG. 8, the adhesive tape application system 50 having the second alternative configuration may be substantially the same as the adhesive tape application system 50 in FIG. 1A. However, in the adhesive tape application system 50 having the second alternative configuration, the laminating unit 12 may include a vacuum laminating unit. In particular, the laminating unit 12 may include a vacuum chamber and the laminating unit 12 may perform a vacuum lamination process to adhere the adhesive tape 10 to the workpiece 20 (e.g., semiconductor wafer).

In the vacuum lamination process, the adhesive tape 10 may be laminated onto the surface of the workpiece 20 under controlled pressure and vacuum conditions. The workpiece 20 may be prepared and placed in the workpiece stage 11 (e.g., vacuum chuck, holder, etc.) inside the laminating unit 12. The workpiece stage 11 may be located in a vacuum chamber 12c of the laminating unit 12.

The adhesive tape 10 may be dispensed, treated by the photo-treatment device 30 and advanced in the adhesive tape advancing direction so that the treated portion 10i (e.g., see FIG. 1B) is positioned on and aligned with the workpiece 20. The vacuum chamber 12c (e.g., lamination area) may then be sealed and evacuated to create a vacuum environment in the vacuum chamber 12c. The vacuum environment may help eliminate air pockets or bubbles between the workpiece 20 and the adhesive tape 10 during the lamination process, ensuring a uniform and consistent bond. The laminating unit 12 may also include a platen or lamination head (not shown) that applies an even pressure across a surface of the adhesive tape 10, bonding the adhesive tape 10 to the workpiece 20.

After the vacuum lamination process is completed, the vacuum on the vacuum chamber may be released. If necessary, any excess portion the adhesive tape 10 may then be cut around a perimeter of the workpiece 20. It should be noted that the laminating unit 12 in the second alternative embodiment of FIG. 8 (e.g., using a vacuum lamination process) may also be used in the adhesive tape application system 50 having the first alternative configuration in FIG. 5 and in the adhesive tape application system 600 in FIG. 6. Other types of laminating units besides a roller type and vacuum type may alternatively or additionally be used in the adhesive tape application system 50 in FIGS. 1A, 5 and 8 and the adhesive tape application system 600 in FIG. 6.

Referring to FIGS. 1A-8, an adhesive tape application system 50, 600 may include an adhesive tape dispenser 102 configured to dispense adhesive tape 10, a laminating unit 12 configured to laminate the adhesive tape 10 on a workpiece 20, and a photo-treatment device 30 between the adhesive tape dispenser 102 and the laminating unit 12 and configured to perform photo-treatment of the adhesive tape 10 to tune an adhesive strength of the adhesive tape 10.

In an embodiment, the photo-treatment device 30 may be configured to perform photo-treatment of the adhesive tape 10 after the adhesive tape 10 may be dispensed from the adhesive tape 10 dispenser 102 and before the adhesive tape 10 may be laminated on the workpiece 20. In an embodiment, the photo-treatment device 30 may include a light source 31 and the photo-treatment device 30 may be configured to perform the photo-treatment by illuminating a portion of the adhesive tape 10 with light from the light source 31. In an embodiment, the light source 31 may include one of a bar-type light source or plate-type light source. A wavelength of the light from the light source 31 may be in a range from 200 nm to 700 nm. In an embodiment, a light-to-tape distance D2 between the light source 31 and the portion of the adhesive tape 10 being treated by the light from the light source 31 may be in a range from 0.1 cm to 30 cm. In an embodiment, a distance D1 between a photo-treatment location where the light source 31 treats (i.e., illuminates) the portion of the adhesive tape 10 and a lamination location where the laminating unit 12 laminates the treated portion 10i of the adhesive tape 10 on the workpiece 20 may be less than 2 meters. In an embodiment, the photo-treatment device 30 may be configured to treat the portion of adhesive tape 10 by exposing the portion of adhesive tape 10 to the light from the light source 31 for an exposure time in a range from 0.1 second to 1000 seconds. In an embodiment, the adhesive tape application system 50, 600 may further include a control unit 200 configured to control a setting of the photo-treatment device 30, wherein the setting may include at least one of a light wavelength of the light from the light source 31, a light-to-tape distance D2 between the light source 31 and the adhesive tape 10, a light intensity of the light from the light source 31 and an exposure time of exposing the portion of adhesive tape 10 to the light from the light source 31. The control unit 200 may be further configured to control a setting of the adhesive tape dispenser 102 and a setting of the laminating unit 12. In an embodiment, the adhesive tape application system 50, 600 may further include an alignment and positioning device 108 configured to precisely align the adhesive tape 10 with a surface of the workpiece 20 before application of the adhesive tape 10 to the workpiece 20, a workpiece handling device 110 configured to transport the workpiece 20 and hold the workpiece 20 during the performing of the lamination by the laminating unit 12, and a cutting tool 116 configured to cut the adhesive tape 10 around a perimeter of the workpiece 20 after the adhesive tape 10 has been laminated on the workpiece 20, wherein the control unit 200 may be further configured to control a setting of at least one of the alignment and positioning device 108, the workpiece handling device 110 and the cutting tool 116. In an embodiment, the light from the light source 31 may include a wavelength in an ultraviolet (UV) wavelength range and the adhesive tape 10 may include an acrylic-based UV adhesive. The workpiece 20 may include a semiconductor wafer including a lamination surface including at least one of silicon, silicon carbide (SiC), solder, an organic polymer layer, a polyimide (PI) layer, a glycol ether-type protection layer, a molding layer, an underfill layer and a metal layer (e.g., copper layer, aluminum layer, etc.). In an embodiment, the adhesive tape 10 may include one of back grinding tape, dicing tape, or protection tape.

Referring again to FIGS. 1A-8, a method of applying adhesive tape 10 to a workpiece 20 may include dispensing the adhesive tape 10, after the dispensing of the adhesive tape 10, modifying an adhesive strength of the portion of the adhesive tape 10, and after the performing of the photo-treatment, laminating the treated portion 10i of the adhesive tape 10 on a workpiece 20. The performing of the photo-treatment may include photo-treating the portion of the adhesive tape 10 with light from a light source 31 of a photo-treatment device 30, wherein a wavelength of the light from the light source 31 may be in a range from 200 nm to 700 nm. The photo-treating the portion of the adhesive tape 10 may include photo-treating the portion of the adhesive tape 10 such that a light-to-tape distance D2 between the light source 31 and the portion of the adhesive tape 10 may be in a range from 0.1 cm to 30 cm. The photo-treating the portion of the adhesive tape 10 may include photo-treating the portion of the adhesive tape 10 such that an exposure time of exposing the portion of adhesive tape 10 to the light from the light source 31 may be in a range from 0.1 second to 1000 seconds. The performing of the photo-treatment may include controlling a setting of the photo-treatment device 30, wherein the setting may include at least one of a light wavelength of the light from the light source 31, a light-to-tape distance D2 between the light source 31 and the adhesive tape 10, a light intensity of the light from the light source 31 and an exposure time of exposing the portion of adhesive tape 10 to the light from the light source 31.

Referring again to FIGS. 1A-8, an adhesive tape application system 50, 600 may include an adhesive tape dispenser 102 configured to dispense adhesive tape 10, a laminating unit 12 configured to laminate the adhesive tape 10 on a workpiece 20, a tension control unit 106 between the adhesive tape dispenser 102 and the laminating unit 12 and configured to maintain tension of the adhesive tape 10, and a photo-treatment device 30 configured to perform photo-treatment of the adhesive tape 10 to tune an adhesive strength of the adhesive tape 10, wherein a location of the photo-treatment device 30 may be one of between the adhesive tape dispenser 102 and the tension control unit 106, or between the tension control unit 106 and the laminating unit 12.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An adhesive tape application system, comprising:
an adhesive tape dispenser configured to dispense adhesive tape;
a laminating unit configured to laminate the adhesive tape on a workpiece; and
a photo-treatment device disposed between the adhesive tape dispenser and the laminating unit and configured to perform photo-treatment of the adhesive tape to tune an adhesive strength of the adhesive tape.

2. The adhesive tape application system of claim 1, wherein the photo-treatment device is configured to perform photo-treatment of the adhesive tape after the adhesive tape is dispensed from the adhesive tape dispenser and before the adhesive tape is laminated on the workpiece.

3. The adhesive tape application system of claim 1, wherein the photo-treatment device comprises a light source and the photo-treatment device is configured to perform the photo-treatment by treating a portion of the adhesive tape by illuminating the adhesive tape with light from the light source.

4. The adhesive tape application system of claim 3, wherein the light source comprises one of a bar-type light source or plate-type light source.

5. The adhesive tape application system of claim 3, wherein a wavelength of the light from the light source is in a range from 200 nm to 700 nm.

6. The adhesive tape application system of claim 3, wherein a distance between the light source and the portion of the adhesive tape being treated by the light from the light source is in a range from 0.1 cm to 30 cm.

7. The adhesive tape application system of claim 3, wherein a distance between a photo-treatment location where the light source illuminates the portion of the adhesive tape and a lamination location where the laminating unit laminates the treated portion of the adhesive tape on the workpiece is less than 2 meters.

8. The adhesive tape application system of claim 3, wherein the photo-treatment device is configured to treat the portion of the adhesive tape by illuminating the portion of the adhesive tape with the light from the light source for an exposure time in a range from 0.1 second to 1000 seconds.

9. The adhesive tape application system of claim 3, further comprising:
a control unit configured to control a setting of the photo-treatment device, wherein the setting comprises at least one of a light wavelength of the light from the light source, a light-to-tape distance between the light source and the adhesive tape, a light intensity of the light from the light source and an exposure time of exposing the portion of the adhesive tape to the light from the light source.

10. The adhesive tape application system of claim 9, wherein the control unit is further configured to control a setting of the adhesive tape dispenser and a setting of the laminating unit.

11. The adhesive tape application system of claim 9, further comprising:
an alignment and positioning device configured to align the adhesive tape with a surface of the workpiece before application of the adhesive tape to the workpiece;
a workpiece handling device configured to transport the workpiece and hold the workpiece during the performing of the lamination by the laminating unit; and
a cutting tool configured to cut the adhesive tape around a perimeter of the workpiece and the adhesive tape that has been laminated on the workpiece, wherein the control unit is further configured to control a setting of at least one of the alignment and positioning device, the workpiece handling device and the cutting tool.

12. The adhesive tape application system of claim 3, wherein the light from the light source comprises a wavelength in an ultraviolet (UV) wavelength range and the adhesive tape comprises an acrylic-based UV adhesive.

13. The adhesive tape application system of claim 1, wherein the workpiece comprises a semiconductor wafer including a lamination surface comprising at least one of silicon, silicon carbide (SiC), solder, an organic polymer layer, a polyimide (PI) layer, a glycol ether-type protection layer, a molding layer, an underfill layer, and a metal layer.

14. The adhesive tape application system of claim 1, wherein the adhesive tape comprises one of back grinding tape, dicing tape, or protection tape.

15. A method of applying adhesive tape to a workpiece, the method comprising:
dispensing the adhesive tape;
modifying an adhesive strength of the portion of the adhesive tape; and
laminating the treated portion of the adhesive tape on the workpiece.

16. The method of claim 15, wherein modifying an adhesive strength of the portion of the adhesive tape comprises photo-treating the portion of the adhesive tape with light from a light source of a photo-treatment device, wherein a wavelength of the light from the light source is in a range from 200 nm to 700 nm.

17. The method of claim 16, wherein the photo-treating the portion of the adhesive tape comprises photo-treating the portion of the adhesive tape such that a distance between the light source and the portion of the adhesive tape is in a range from 0.1 cm to 30 cm.

18. The method of claim 16, wherein the photo-treating the portion of the adhesive tape comprises photo-treating the portion of the adhesive tape such that an exposure time of exposing the portion of adhesive tape to the light from the light source is in a range from 0.1 second to 1000 seconds.

19. The method of claim 16, wherein the photo-treating the portion of the adhesive tape comprises controlling a setting of the photo-treatment device, wherein the setting comprises at least one of a light wavelength of the light from the light source, a light-to-tape distance between the light source and the adhesive tape, a light intensity of the light from the light source and an exposure time of exposing the portion of the adhesive tape to the light from the light source.

20. An adhesive tape application system, comprising:
an adhesive tape dispenser configured to dispense adhesive tape;
a laminating unit configured to laminate the adhesive tape on a workpiece;
a tension control unit between the adhesive tape dispenser and the laminating unit and configured to maintain tension of the adhesive tape; and
a photo-treatment device configured to perform photo-treatment of the adhesive tape to tune an adhesive strength of the adhesive tape, wherein a location of the photo-treatment device is one of between the adhesive tape dispenser and the tension control unit, or between the tension control unit and the laminating unit.
